(19) United States
(12) Patent Application Publication
(10) Pub. No.: US 2012/0256171 A1
(43) Pub. Date: Oct. 11, 2012

(54) PHOSPHINE OXIDE COMPOUND, ORGANIC ELECTROLUMINESCENCE ELEMENT, PRODUCTION METHOD AND USES THEREOF

(75) Inventors: Takashi TERASHIMA, Tokyo (JP); Katsumasa HIROSE, Tokyo (JP)

(73) Assignee: SHOWA DENKO K.K., Tokyo (JP)

(21) Appl. No.: 13/442,440

(22) Filed: Apr. 9, 2012

(30) Foreign Application Priority Data
Apr. 8, 2011 (JP) 2011-086565

(51) Int. Cl. H01L 51/54; H01L 51/40; C07F 9/58

(52) U.S. Cl. 257/40; 546/22; 438/29; 257/E51.024; 257/E51.018

(57) ABSTRACT

A compound having a stable deposition rate suitable for forming an electron-transporting layer of an organic El element. The compound is represented by the following formula (1):

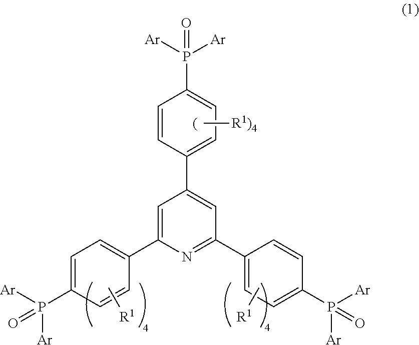

wherein in the formula (1), plural R¹ are each an alkyl group having 1 to 10 carbon atoms, an alkoxy group having 1 to 10 carbon atoms, a halogen atom, or a hydrogen atom, and may be the same as or different from one another; and plural Ar are each a monovalent substituted or unsubstituted aromatic group optionally containing a hetero atom, and may be the same as or different from one another.

### BACKGROUND OF THE INVENTION

1. Field of the Invention

The present invention relates to a phosphine oxide compound, in more detail, relates to a phosphine oxide compound suitable as an electron-transporting material used for an organic electroluminescence (hereinafter, also referred to as an “organic EL”) element, an organic EL element using the phosphine oxide compound, and a production method and uses thereof.

2. Description of the Related Art

In recent years, the development of materials and the improvement of organic EL element structures have been actively pursued. Still, there is a demand to further improve the luminescence efficiency and the electric power efficiency. The organic EL element has a laminate structure comprising thin films each ranging from several nm to some dozen nm. Each layer is referred to, according to its performance, as a hole injecting layer, a hole transport layer, a luminescent layer, a hole blocking layer, an electron transport layer, an electron injecting layer or the like.

The film thickness of the individual layers is closely related to the transfer of carriers of the element: carriers pass through a thin layer quickly, but pass through a thick layer slowly. Thus, a change in film thickness leads to a change in carrier balance and in a luminescence position, resulting in a change in the efficiency, life, chromaticity and the like of the organic EL element. It is thus extremely important to control the film thickness in the element production.

As a process for forming the films of the individual layers, a dry process such as vacuum deposition method, and a wet process such as ink jet method and spin coating method are known. Organic EL elements are supposedly susceptible to moisture, and at present, organic elements having improved luminescence efficiency are obtained using a dry process employing no solvent, rather than a wet process employing solvents. Therefore, there is active development of processes using a vacuum deposition method. Among them, there is active development of deposition apparatus to achieve a uniform deposition rate and thereby control the film thickness (Patent Literature JP-A-2009-174027). On the other hand, there is active development of stable compounds having a uniform deposition rate.

In general, it is common for an organic EL element to be formed in the order of: anode/hole transport layer/luminescent layer/electron transport layer/cathode. The electron transport layer is formed at a stage where the element production is near its completion. Instability in the film formation of this layer considerably lowers the yield of the element. It is therefore important to develop materials capable of being deposited with stability at a uniform deposition rate to form electron-transporting layers such as a hole blocking layer, an electron transport layer and an electron injecting layer.

As materials of these layers, phenanthroline compounds, aluminumquinolinol complex compounds, imidazole compounds and the like have generally been employed. Furthermore, in recent years, the development of phosphine oxide compounds is underway (Non-Patent Literature 1), but the deposition stability thereof is insufficient.
Non-Patent Literature 1: Chem. Mater., 22, 5678 (2010)

3. Problems to be Solved by the Invention

It is difficult to stably produce a film with a uniform thickness from a compound having an unstable deposition rate, and using such a compound to form a layer of the organic EL element decreases the yield of the organic EL element.

### SUMMARY OF THE INVENTION

The present invention has been made in order to solve the above problems of the conventional art. It is therefore an object of the present invention to provide a novel compound having a stable deposition rate which is suitable to form an electron-transporting layer of an organic El element. It is another object of the present invention to stably provide an organic EL element comprising an electron transporting layer having a uniform thickness.

Following extensive studies, the present inventors have found that a specific phosphine oxide compound is stable in terms of deposition rate. Based on this finding, the present invention has been made.

The present invention relates to, for example, the following [1] to [8].

[1] A compound represented by the following formula (1):

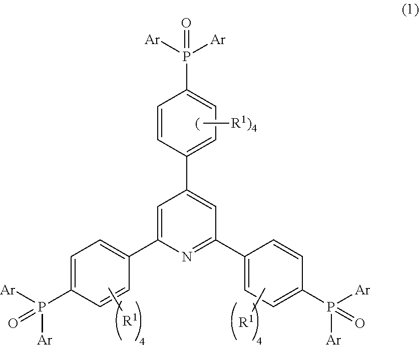

wherein in the formula (1), plural R¹ are each an alkyl group having 1 to 10 carbon atoms, an alkoxy group having 1 to 10 carbon atoms, a halogen atom, or a hydrogen atom, and may be the same as or different from one another; and plural Ar are each a monovalent substituted or unsubstituted aromatic group optionally containing a hetero atom, and may be the same as or different from one another.

[2] The compound as described in the above [1], wherein all of the Ar groups are phenyl groups.

[3] The compound as described in the above [1] or [2], wherein all of R¹ are each hydrogen atoms.

[4] An organic electroluminescence element, comprising an anode, a luminescent layer, a phosphine oxide-containing layer and a cathode laminated in this order, the phosphine oxide-containing layer comprising a compound represented by the following formula (1):

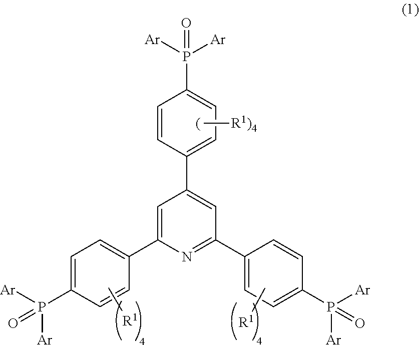

wherein in the formula (1), plural R¹ are each an alkyl group having 1 to 10 carbon atoms, an alkoxy group having 1 to 10 carbon atoms, a halogen atom, or a hydrogen atom, and may be the same as or different from one another; and plural Ar are each a monovalent substituted or unsubstituted aromatic group optionally containing a hetero atom, and may be the same as or different from one another.

[5] The organic electroluminescence element as described in the above [4], further comprising an anode buffer layer adjacent to the anode between the anode and the luminescent layer.

[6] A method for producing an organic electroluminescence element, comprising the steps of:

forming a phosphine oxide-containing layer by depositing a compound represented by the following formula (1) on a luminescent layer formed on an anode, and

forming a cathode on the phosphine oxide-containing layer;

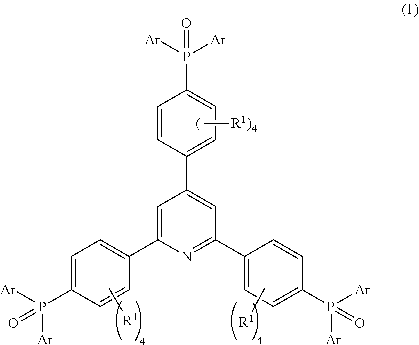

wherein in the formula (1), plural R¹ are each an alkyl group having 1 to 10 carbon atoms, an alkoxy group having 1 to 10 carbon atoms, a halogen atom, or a hydrogen atom, and may be the same as or different from one another; and plural Ar are each a monovalent substituted or unsubstituted aromatic group optionally containing a hetero atom, and may be the same as or different from one another.

[7] A display apparatus comprising the organic electroluminescence element as described in [4] or [5] above.

[8] A light irradiation apparatus comprising the organic electroluminescence element as described in [4] or [5] above.

### EFFECT OF THE INVENTION

The phosphine oxide compound of the present invention is more stable in terms of decomposition rate, as compared with conventional electron transporting materials used for organic compound layers of organic EL elements. Therefore, by using the phosphine oxide compound of the present invention as a material for an electron-transporting layer, a film with a uniform thickness is stably produced.

Furthermore, the organic EL element of the present invention comprising a layer formed from the phosphine oxide compound of the present invention is excellent in electric power efficiency.

### BRIEF DESCRIPTION OF DRAWINGS

FIG. 1 is a sectional view of an example of the organic EL element according to the present invention.

FIG. 2 is a sectional view of an example of the organic EL element according to the present invention.

FIG. 3 is a sectional view of an example of the organic EL element according to the present invention.

### DESCRIPTION OF REFERENCE NUMERALS

Reference numerals used to identify structural features in the drawings including the following.
1 . . . Substrate
2 . . . Anode
3 . . . Luminescent layer
4 . . . Phosphine oxide-containing layer
5 . . . Cathode
6 . . . Dielectric layer
7 . . . Through-hole or through-groove

### DETAILED DESCRIPTION OF THE INVENTION

### <1. Structure of Element>

An organic EL element of the present invention comprises an anode, a luminescent layer, a phosphine oxide-containing layer, and a cathode laminated in this order.

A method for producing an organic electroluminescence element of the present invention comprises the steps of:

forming a phosphine oxide-containing layer on a luminescent layer formed on an anode, and

forming a cathode on the phosphine oxide-containing layer.

In the present invention, an “upper” direction means a direction from the anode to the cathode.

The organic EL element of the present invention may comprise, in addition to the above layers, an anode buffer layer, a hole transport layer, an electron blocking layer, a hole blocking layer, an electron transport layer or a cathode buffer layer. The hole blocking layer is adjacent to the phosphine oxide-containing layer side of the luminescent layer. The electron transport layer is adjacent to the luminescent layer side or the cathode side of the phosphine oxide-containing layer, or both sides of the phosphine oxide-containing layer.

Each of the above layers may be composed of a single layer, or two or more layers.

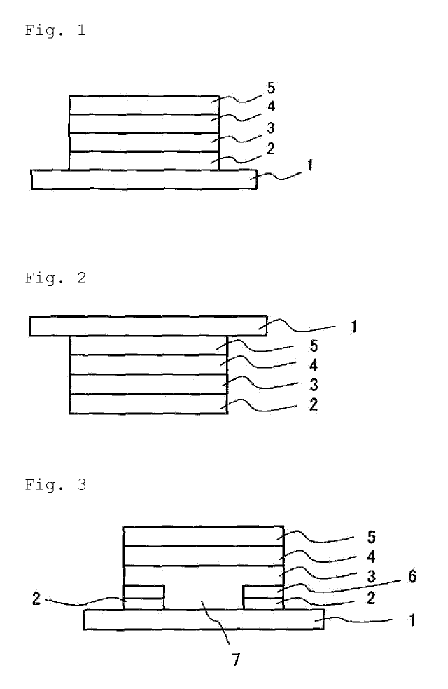

FIG. 1 shows a sectional view of an example of a structure of the organic EL element of the present invention; between an anode 2 and a cathode 5, a luminescent layer 3, and a phosphine oxide-containing layer 4 are provided in order. As shown in FIG. 2, the transparent substrate 1 may be provided so as to contact the cathode 5.

The structure of the organic EL element of the present invention is not limited to the example of FIG. 1 ((1) anode/luminescent layer/phosphine oxide-containing layer/cathode). Further exemplary structures are as follows.

(2) anode/luminescent layer/phosphine oxide-containing layer/cathode buffer layer/cathode
(3) anode/anode buffer layer/luminescent layer/phosphine oxide-containing layer/cathode buffer layer/cathode
(4) anode/anode buffer layer/luminescent layer/hole blocking layer/phosphine oxide-containing layer/cathode buffer layer/cathode
(5) anode/anode buffer layer/luminescent layer/electron transport layer/phosphine oxide-containing layer/cathode buffer layer/cathode
(6) anode/anode buffer layer/luminescent layer/phosphine oxide-containing layer/electron transport layer/cathode buffer layer/cathode
(7) anode/anode buffer layer/hole transport layer/luminescent layer/phosphine oxide-containing layer/cathode buffer layer/cathode
(8) anode/anode buffer layer/electron blocking layer/luminescent layer/phosphine oxide-containing layer/cathode buffer layer/cathode

The luminescent layer 3 shown in FIG. 1 is a single layer, but the luminescent layer 3 may be composed of two or more layers.

Another organic EL element of the present invention, as shown in FIG. 3, comprises a substrate 1, an anode 2, a dielectric layer 6, (the anode 2 and the dielectric layer 6 each have a through-hole or through-groove 7), a luminescent layer 3, a phosphine oxide-containing layer 4, and a cathode 5 laminated in this order, wherein the luminescent layer 3 is contacted, via the through-hole or through-groove 7, with the substrate 1. According to the organic EL element thus constituted, light extraction efficiency is improved, and luminescence efficiency is further increased.

Examples of materials that may be used to form the dielectric layer 6 are silicon nitride, boron nitride, metal nitrides such as aluminum nitride, silicon oxide (silicon dioxide) and metal oxides such as aluminum oxide. The dielectric layer 6 has a thickness of about 10 nm to 500 nm. The width of the through-hole or through-groove is defined as a distance on a shorter axis (a shortest distance) stretching from one end to the other end of the through-hole or through-groove, and the width is not more than 10 μm. A distance on a shorter axis (a shortest distance) between neighboring through-holes or neighboring through-grooves is also not more than 10 nm.

In the present specification, the electron-transporting compound, the hole-transporting compound and the luminescent compound are each referred to as an “organic EL compound”. A compound layer consisting of all of these compounds or one or more of these compounds is referred to an “organic EL compound layer”.

### <2. Anode>

As the anode, substances that may be employed are preferably those having a surface resistivity in the temperature range of −5 to 80° C. of not more than 1,000Ω/□, more preferably not more than 100Ω/□.

In the case where light is extracted from the anode side of the organic EL element, the anode needs to be transparent to visible light (average transmittance for a light of 380 to 680 nm: not less than 50%). In view of this, examples of a material for the anode are indium tin oxide (ITO) and indium zinc oxide (IZO). Of these, ITO is preferable, which is easy to obtain as a material for the anode of the organic EL element.

In the case where light is extracted from the cathode side of the organic EL element, light transmittance of the anode is not restricted, and examples of a material that may be employed for the anode are ITO, IZO, stainless steel; a simple metal of copper, silver, gold, platinum, tungsten, titanium, tantalum or niobium; and an alloy of these metals.

In order to realize high light transmittance, the thickness of the anode is preferably 2 to 300 nm in the case where light is extracted from the anode side, and is preferably 2 nm to 2 mm in the case where light is extracted from the cathode side.

### <3. Anode Buffer Layer>

The organic EL element of the present invention preferably comprises an anode buffer layer which is adjacent to the anode. The provision of the anode buffer layer can adjust the balance between the transfer of electrons promoted in the phosphine oxide-containing layer and the transfer of holes injected from the anode, and this can further improve the durability of the organic EL element of the present invention.

The anode buffer layer can be prepared by a dry process such as a resistance heating deposition method and a high-frequency plasma treatment. Preferred is the high-frequency plasma treatment, in which the application of glow discharge to an organic substance gas precipitates the organic substance gas on a solid layer as a solid. By this treatment, an anode buffer layer is obtained which has excellent adhesion and high durability.

Compounds to be employed for the film formation using the high-frequency plasma treatment have no particular limitation, as long as they are capable of farming an anode buffer layer having good adhesion with the anode surface and the organic EL compound layer formed thereon. In the case where the organic EL compound layer, described below, is prepared by a coating process, by forming the anode buffer layer from a fluorocarbon film obtained by subjecting a gaseous fluorocarbon such as CF₄, C₃F₈, C₄F₁₀, CHF₃, C₂F₄ and C₄F₈ to high-frequency treatment, the organic EL compound layer can be stably formed on the fluorocarbon film.

The anode buffer layer may be prepared by a wet process, i.e., by coating the anode with an anode buffer layer-forming material.

In this case, coating methods suitably employed for the film formation include spin coating, casting, microgravure coating, gravure coating, bar coating, roll coating, wire bar coating, dip coating, spray coating, screen printing, flexography, offset printing and ink jet printing.

As compounds suitably employed for the film formation using the wet process, any compounds are usable as long as they are capable of forming an anode buffer layer having good adhesion with the anode surface and with the organic EL compounds contained in an upper layer thereof. Examples are conductive polymers such as PEDOT-PSS, which is a mixture of poly(3,4)-ethylenedioxythiophene and polystyrene sulfonate, and PANT, which is a mixture of polyaniline and polystyrene sulfonate.

Furthermore, it is also preferred to use as a material for the anode buffer layer, a composition comprising a hole-transporting high-molecular weight compound and an electron accepting compound capable of forming a charge transfer complex. As the hole-transporting high-molecular weight compound, examples are products resulting from the polymerization of hole-transporting polymerizable compounds, such as compounds represented by the following formulae (E-1) to (E-9).

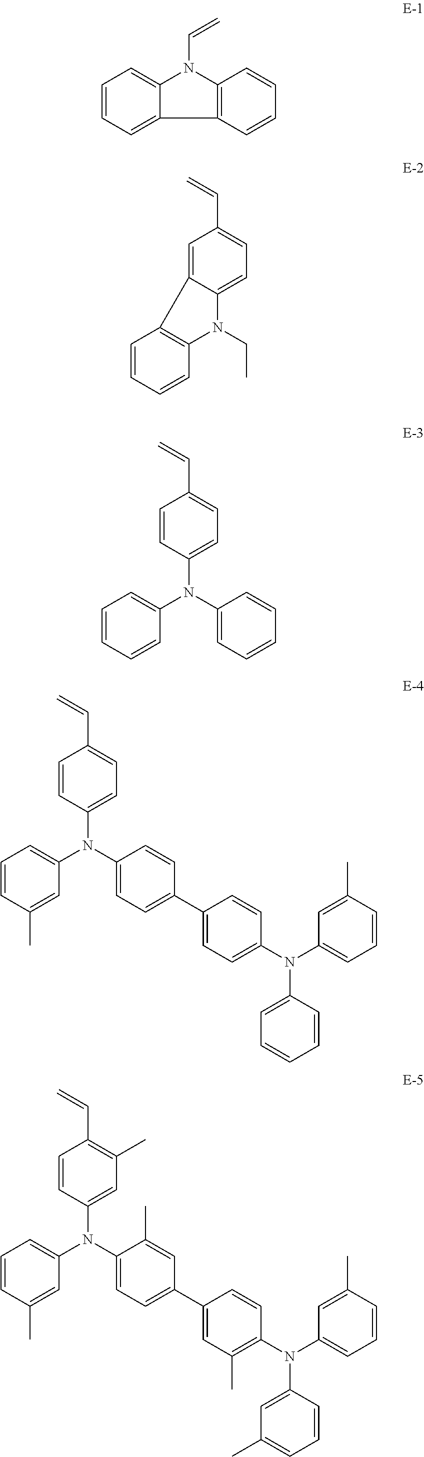

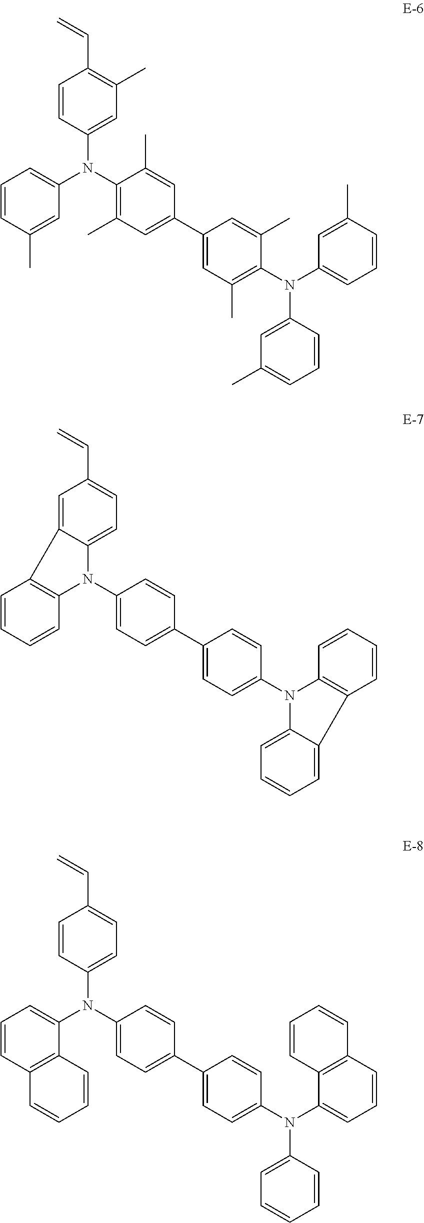

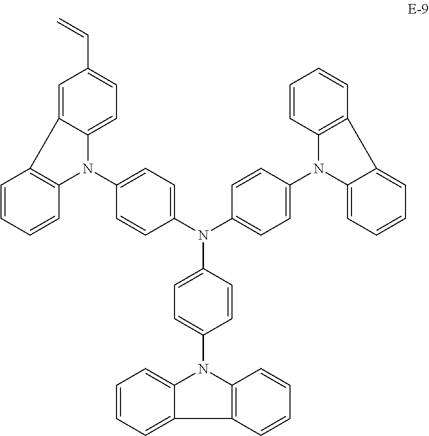

Examples of the electron accepting compound capable of forming the charge transfer complex include N,N′-dicyano-2,3,5,6-tetrafluoro-1,4-quinonediimine (F4DCNQI), N′N-dicyano-2,5-dichloro-1,4-quinonediimine (C12DCNQI), N,N′-dicyano-2,5-dichloro-3,6-difluoro-1,4-quinonediimine (C12F2DCNQI), N′N-dicyano-2,3,5,6,7,8-hexafluoro-1,4-naphtoquinonediimine (F6DCNNOI), 1,4,5,8-tetrahydro-1,4,5,8-tetrathia-2,3,6,7-tetracyanoanthraquinone (CN4TTAQ), 7,7,8,8-tetracyanoquinodimethane (TCNQ), 2,3,5,6-tetrafluoro-7,7,8,8-tetracyanoquinodimethane (F4TCNQ), 2,5-bis(2-hydroxyethoxy)-7,7,8,8-tetracyanoquinodimethane, 2,5-difluoro-7,7,8,8-tetracyanoquinodimethane, bis(tetrabutylammonium)tetracyanodiphenoquinodimethanide, 2,5-dimethyl-7,7,8,8-tetracyanoquinodimethane, 2-fluoro-7,7,8,8-tetracyanoquinodimethane, and 11,11,12,12-tetracyanonaphto-2,6-quinodimethane.

Of these, TCNQ and F4TCNQ are preferred in terms of having a high solubility in an organic solvent (e.g., toluene) and being capable of forming an anode buffer layer with high uniformity.

If the anode buffer layer is prepared by a wet process, an organic solvent such as toluene and isopropyl alcohol may be added to the conductive polymer or the composition. Further, a third component such as a surfactant may be added to the conductive polymer or the composition. As the surfactant, a surfactant containing a group selected from the group consisting of an alkyl group, an alkylaryl group, a fluoroalkyl group, an alkylsiloxane group, a sulfate, a sulfonate, a carboxylate, an amide, a betaine structure and a quaternary ammonium group is suitably employed, and a fluoride-based non-ionic surfactant may also be used.

The thickness of the anode buffer layer is preferably 5 to 50 nm, more preferably 10 to 30 nm so as to allow the anode buffer layer to sufficiently exhibit its effect as a buffer layer and to prevent an increase in voltage needed to drive the organic EL element.

### <4. Organic EL Compound Layer>

In the organic EL element of the present invention, as the organic EL compound layers, i.e., the luminescent layer, the hole transport layer and the electron transport layer, any of low-molecular weight compounds and high-molecular weight compounds may be employed.

Organic EL compounds for forming the luminescent layer of the organic EL element of the present invention include, for example, luminescent low-molecular weight compounds and luminescent high-molecular weight compounds that are described in Yutaka Ohmori: Oyo Butsuri (Applied Physics), Vol. 70, No. 12, pp. 1419-1425 (2001). Of them, the luminescent high-molecular weight compounds are preferred in terms of being able to simplify an element preparation process, and phosphorescent compounds are preferred in terms of having high luminescence efficiency. Therefore, phosphorescent high-molecular weight compounds are particularly preferred.

The luminescent high-molecular weight compounds can be classified into conjugated luminescent high-molecular weight compounds and non-conjugated luminescent high-molecular weight compounds. Of these, the non-conjugated luminescent high-molecular weight compounds are preferred.

For the above reasons, as the luminescent material suitably employed in the present invention, particularly preferred are phosphorescent non-conjugated high-molecular weight compounds (luminescent materials that are the phosphorescent high molecules and are the non-conjugated luminescent high-molecular weight compounds).

The luminescent layer in the organic EL element of the present invention, preferably, comprises at least a phosphorescent high-molecular weight compound having, in one molecule, a phosphorescent unit that emits phosphorescence and a carrier transporting unit that transports a carrier. The phosphorescent high-molecular weight compound is obtained by copolymerizing a phosphorescent compound having a polymerizable substituent and a carrier transporting compound having a polymerizable substituent. The phosphorescent compound is a metal complex containing one metal element selected from iridium, platinum and gold. Among them, the iridium complex is preferred.

More specific examples of the phosphorescent high-molecular weight compounds and synthesis methods thereof are disclosed in, for example, Patent Literatures JP-A-2003-342325, JP-A-2003-119179, JP-A-2003-206320, JP-A-2003-147021, JPA-2003-171391, JP-A-2004-346312 and JP-A-2005-97589.

According to the present invention, high durability and high luminescence efficiency are accomplished, even in the case of an organic EL element using a blue phosphorescent compound as a luminescent material. In such an element, it has conventionally been difficult to simultaneously achieve high durability and high luminescence efficiency.

The blue phosphorescent compound as used herein refers to a compound having a maximum luminescence wavelength of 380 nm to 500 nm, among the phosphorescent compounds. Preferred are compounds having partial structures represented by the following formulae (e1) to (e4).

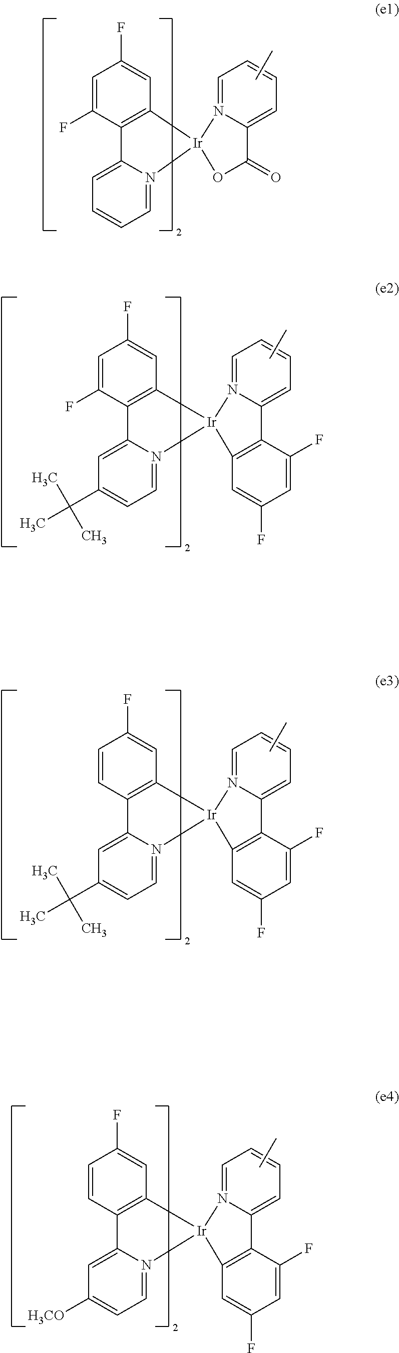

The maximum luminescence wavelength of the phosphorescent compound is a wavelength at which the luminescence intensity peaks in a luminescence spectrum obtained by exciting the phosphorescent compound in the state of a dichloromethane solution at 25° C. with a monochromic light having a wavelength of 350 nm, the solution being prepared such that the absorbance of the monochromatic light having a wavelength of 350 nm would become 0.1, provided that an optical path length is 1 cm.

The luminescent layer in the organic EL element which is produced by the process of the present invention is preferably a layer containing the phosphorescent compound, and may contain a hole-transporting compound or an electron-transporting compound in order to compensate for the carrier transport performance of the luminescent layer. Examples of the hole-transporting compounds used for this purpose include low-molecular weight triphenylamine derivatives, such as TPD (N,N′-dimethyl-N,N′-(3-methylphenyl)-1,1′-biphenyl-4,4′-diamine), α-NPD (4,4′-bis[N-(1-naphthyl)-N-phenylamino]biphenyl) and m-MTDATA (4,4′,4″-tris(3-methylphenylphenylamino)triphenylamine); polyvinylcarbazole; high-molecular weight compounds obtained by introducing polymerizable functional groups into the above triphenylamine derivatives and polymerizing them, such as high-molecular weight compounds of triphenylamine skeleton disclosed in JP-A-08-157575; polyparaphenylenevinylene; and polydialkylfluorene. As the electron-transporting compounds, known electron-transporting compounds can be used, e.g., low-molecular weight materials, such as quinolinol derivative metal complexes, specifically Alq3 (tris(8-hydroxyquinolinato)aluminum (III)), oxadiazole derivatives, triazole derivatives, imidazole derivatives, triazine derivatives and triarylborane derivatives; and high-molecular weight compounds obtained by introducing polymerizable functional groups into the above low-molecular weight electron-transporting compounds and polymerizing them, such as poly PBD disclosed in JP-A-10-1665.

### (Method for Forming Organic EL Compound Layer)

In the case where the organic EL compound is the luminescent high-molecular weight compound, the organic EL compound layer can be formed mainly by a coating method, such as spin coating, casting, microgravure coating, gravure coating, bar coating, roll coating, wire bar coating, dip coating, spray coating, screen printing, flexography, offset printing and ink jet printing.

On the other hand, in the case where the organic EL compound is the luminescent low-molecular weight compound, the organic EL compound layer can be formed mainly by a resistance heating deposition method or an electron beam deposition method.

### <5. Hole Blocking Layer>

In order to inhibit the passing of holes through the luminescent layer and thereby efficiently recombining holes with electrons in the luminescent layer, a hole blocking layer may be provided between the luminescent layer and the phosphine oxide-containing layer so as to be adjacent to the luminescent layer. As the hole blocking layer, a compound can be used which has a deeper highest occupied molecular orbital (HOMO) level than that of the luminescent compound. Examples of such a compound include triazole derivatives, oxadiazole derivatives, phenanthroline derivatives and aluminum complexes.

Moreover, in order to prevent deactivation of exciton by a cathode metal, an exciton blocking layer may be provided adjacent to the cathode side of the luminescent layer. As the exciton blocking layer, a compound having a larger excitation triplet energy than that of the luminescent compound can be used. Examples of such a compound include triazole derivatives, phenanthroline derivatives and aluminum complexes.

### <6. Phosphine Oxide-Containing Layer>

### (Phosphine Oxide-Containing Layer)

The phosphine oxide-containing layer comprises a phosphine oxide compound represented by the following formula (1) (hereinafter, also referred to as a “specific phosphine oxide compound”):

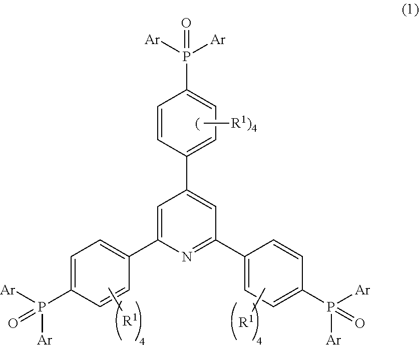

wherein in the formula (1), plural R¹ are each an alkyl group having 1 to 10 carbon atoms, an alkoxy group having 1 to 10 carbon atoms, a halogen atom, or a hydrogen atom, and may be the same as or different from one another; and

plural Ar are each a monovalent substituted or unsubstituted aromatic group optionally containing a hetero atom, and may be the same as or different from one another.

R¹ is preferably an alkyl group having 1 to 4 carbon atoms, or a hydrogen atom, particularly preferably methyl group, ethyl group, or a hydrogen atom.

As the monovalent aromatic group represented by Ar, a substituted or unsubstituted aryl group having 6 to 30 carbon atoms, and a substituted or unsubstituted heterocyclic aromatic group having 2 to 20 carbon atoms can be used; and a substituted or unsubstituted aryl group having 6 to 30 carbon atoms is preferred.

As the substituted or unsubstituted aryl groups having 6 to 30 carbon atoms, groups represented by the following formulae (a) to (n) can be used; and the group represented by the formula (a) is particularly preferred.

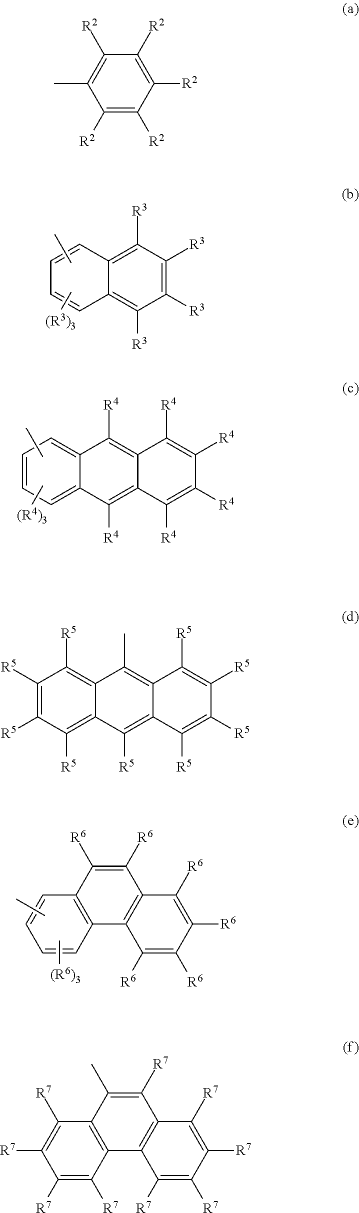

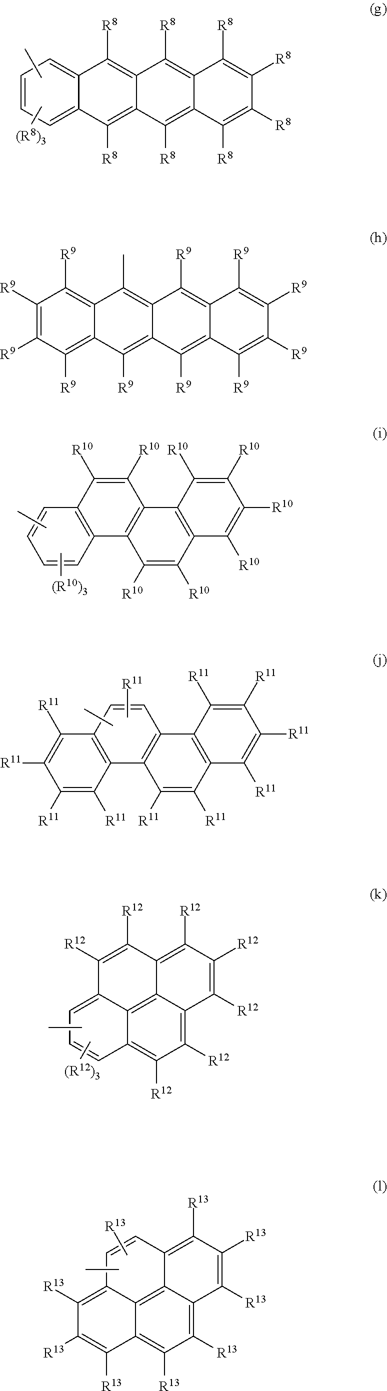

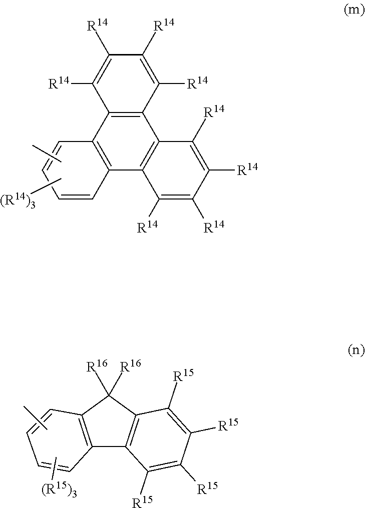

In the formulae (a) to (n), R² to R¹⁵ may be the same as or different from one another, and are each an alkyl group having 1 to 10 carbon atoms, an alkenyl group having 2 to 10 carbon atoms, an alkoxy group having 1 to 10 carbon atoms, a halogen atom, or a hydrogen atom; and R¹⁶ is methyl group or ethyl group. Plural R² may be the same as or different from one another, and the same applies to R³ to R¹⁵. R² to R¹⁵ are each preferably an alkyl group having 1 to 4 carbon atoms, or a hydrogen atom, more preferably methyl group, ethyl group, or a hydrogen atom, particularly preferably a hydrogen atom.

As the substituted or unsubstituted heterocyclic aromatic group having 2 to 20 carbon atoms, groups represented by the following formulae (o) to (x) can be used.

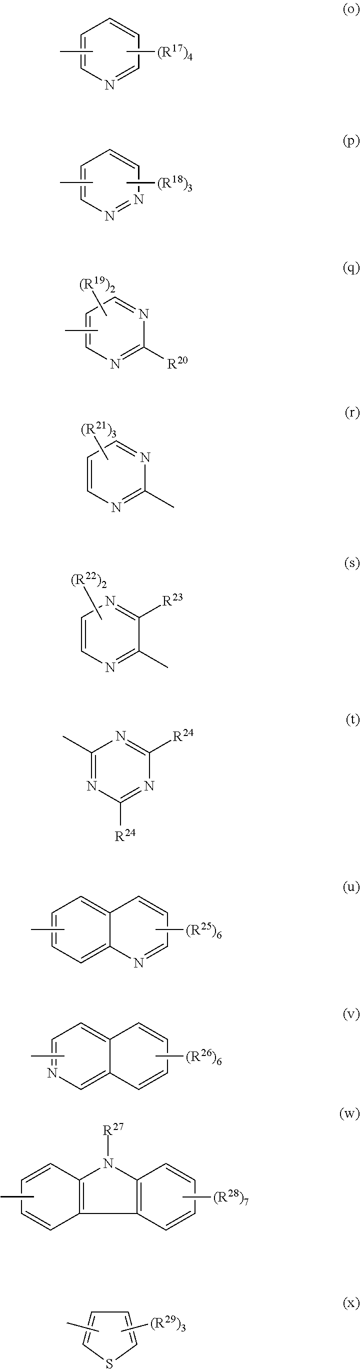

In the formulae (o) to (x), R¹⁷ to R²⁹ may be the same as or different from one another, and is an alkyl group having 1 to 10 carbon atoms, an alkenyl group having 2 to 10 carbon atoms, or a hydrogen atom. Plural R¹⁷ may be the same as or different from one another, and the same applies to R¹⁸ to R²⁹. R¹⁷ to R²⁹ are each preferably an alkyl group having 1 to 4 carbon atoms, or a hydrogen atom, particularly preferably methyl group, ethyl group, or a hydrogen atom.

The phosphine oxide compound is preferably a compound represented by the following formula (2):

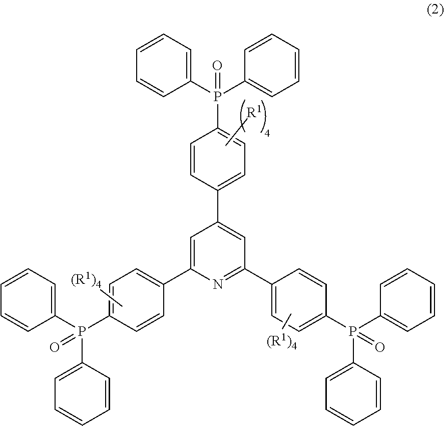

wherein R¹ is as defined above, more preferably a compound represented by the following formulae (a), (b), (c), or (d), and still more preferably the compound represented by formula (a).

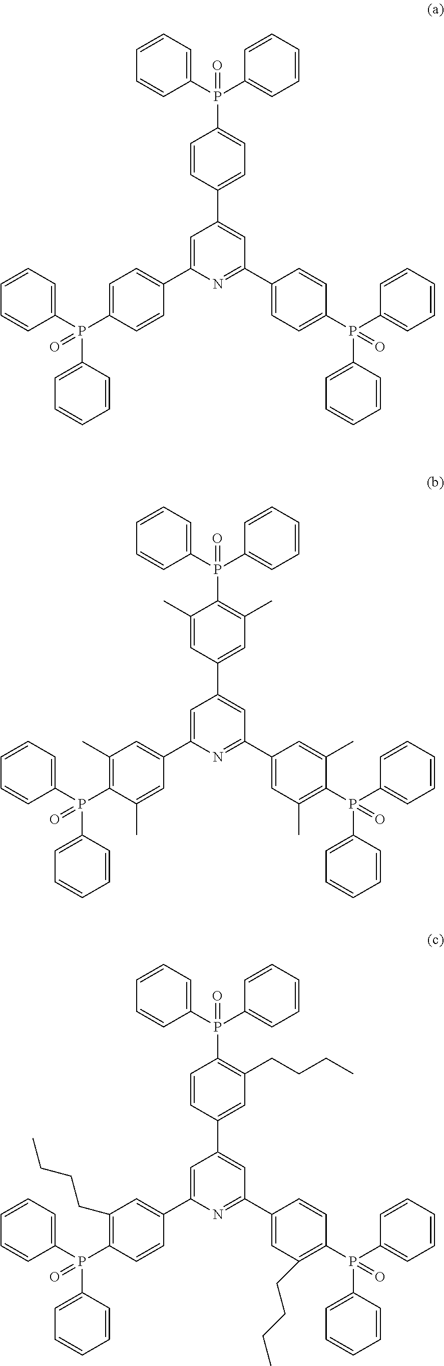

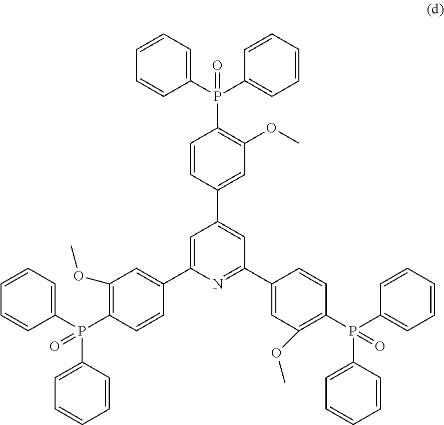

### (Method for Producing Phosphine Oxide Compound)

A method for producing the phosphine oxide compound of the present invention is not particularly limited. The phosphine oxide compound of the present invention can be produced, for example, by the reaction scheme illustrated below.

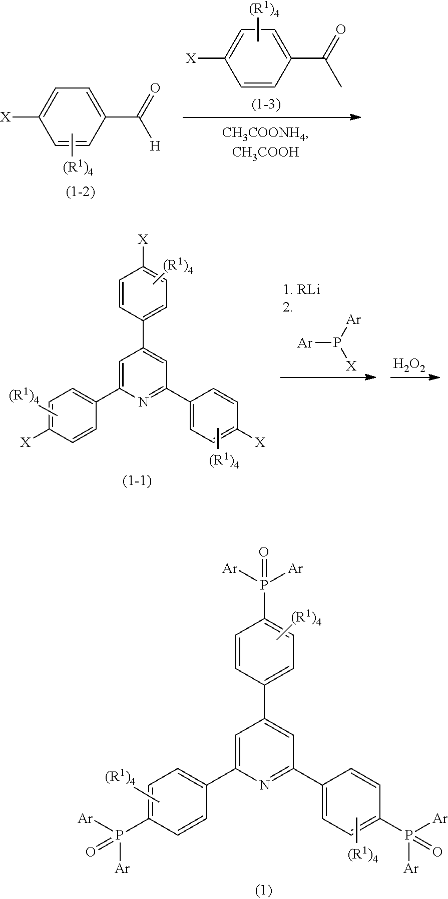

In the formulae, R¹ is an alkyl group having 1 to 10 carbon atoms, an alkoxy group having 1 to 10 carbon atoms, a halogen atom, or a hydrogen atom, and may be the same as or different from one another; the Ar groups are each a monovalent substituted or unsubstituted aromatic group optionally containing a hetero atom, and may be the same as or different from one another; and X is chlorine, bromine, or iodine.

### (i) Synthesis of Compound (1-1)

First, a benzaldehyde derivative represented by the formula (1-2), an acetophenone derivative represented by the formula (1-3), ammonium acetate, and acetic acid are heated at 145 to 155° C. for 2 to 5 hours. The reaction product is purified to obtain a compound represented by the formula (1-1). The heating is carried out preferably under stirring with the raw materials charged in a container such as a round-bottom flask.

### (ii) Synthesis of Phosphine Oxide Compound

The compound (1-1) is dissolved in dehydrated THF, and the resultant solution is cooled to not higher than −60° C. An alkyllithium (hexane solution) such as n-butyllithium (BuLi) is dropped into the solution, and the resultant solution is stirred at a temperature of not higher than −60° C. Then, a diarylphosphine derivative is dropped into the solution. The temperature is increased to room temperature gradually, e.g., at a temperature increasing rate of 0.5 to 2.0° C./min. After stirring at room temperature, aqueous hydrogen peroxide is added, and stirring is carried out at room temperature. The reaction product is purified to obtain the phosphine oxide compound of the present invention, represented by the formula (1).

The phosphine oxide-containing layer has a thickness of about 0.5 to 100 nm, preferably 1 to 50 nm, more preferably 5 to 25 nm.

### (Process for Forming Phosphine Oxide-Containing Layer)

The phosphine oxide-containing layer is formed by depositing the specific phosphine oxide compound on a surface opposite to the anode side of the luminescent layer.

Deposition conditions vary depending on types of the specific phosphine oxide compound, and thus cannot be determined as a rule. However, the following can be mentioned as a guide.

### Heating Method:

Examples include a resistance heating method and an electron beam method.

### Heating Temperature (Deposition Temperature):

The temperature is about 50 to 480° C., preferably 100 to 400° C.

### Substrate Temperature:

The temperature is about −50 to 300° C., preferably 20 to 200° C. Preferably, the substrate is not heated.

### Pressure:

The pressure is about 1.0×10⁻⁷ to 1.0×10⁻⁴ Pa, preferably 1.0×10⁻⁶ to 1.0×10⁻⁵ Pa.

### Deposition Rate:

The deposition rate of the phosphine oxide compound is about 0.01 to 500 Å/s, preferably 0.05 to 10 Å/s.

### <7. Cathode Buffer Layer>

In order to lower a barrier to the injection of electrons from the cathode to the organic layer and thereby enhance electron injection efficiency, a metal layer having a lower work function than that of the cathode is preferably provided as a cathode buffer layer so as to be adjacent to the cathode. Examples of metals with low work function suitably employed for such purpose include alkali metals (Na, K, Rb, Cs), alkaline earth metals (Sr, Ba, Ca, Mg), and rare earth metals (Pr, Sm, Eu, Yb). Further, an alloy or a metal compound such as NaF, MgF₂ and MgO can be also used provided that it has a lower work function than that of the cathode. As a method for forming such a cathode buffer layer, a deposition method, a sputtering method or the like may be employed. The thickness of the cathode buffer layer is preferably 0.05 to 50 nm, more preferably 0.1 to 20 nm, still more preferably 0.5 to 10 nm.

The cathode buffer layer may be formed from a mixture of the above substance having a low work function and an electron-transporting compound. As the electron-transporting compound employed herein, the aforesaid organic compound used for the electron transport layer may be employed. As a film formation method in this case, a co-deposition method may be used. When the film formation by application of a solution is possible, known film formation methods may be used, such as spin coating, dip coating, an ink jet method, printing, spraying and a dispenser method. The thickness of the cathode buffer layer in this case is preferably 0.1 to 100 nm, more preferably 0.5 to 50 nm, still more preferably 1 to 20 nm. Between the cathode and the organic substance layer, a layer comprising a conductive high-molecular weight compound, or a layer comprising a metal oxide, a metal fluoride, an organic insulating material or the like and having an average film thickness of not more than 2 nm may be provided.

### <8. Cathode>

As a material for the cathode of the organic EL element of the present invention, in the case where light is extracted from the anode side, a material which has a low work function and which is chemically stable is suitably employed. Examples of such a material include known cathode materials, such as Al, an MgAg alloy and alloys of Al and alkali metals or alkaline earth metals, such as AlLi and AlCa. In view of chemical stability of the cathode, the work function is preferably not more than 2.9 eV. As a method for forming a film of such a cathode material, a resistance heating deposition method, an electron beam deposition method, a sputtering method, an ion plating method or the like is suitably employed. The thickness of the cathode is preferably 10 nm to 1 μm, more preferably 50 to 500 nm.

In the case where light is extracted from the cathode side, the cathode needs to be transparent to visible light (average transmittance for a light of 380 to 680 nm: not less than 50%). In view of the above, examples of a material for the cathode are indium tin oxide (ITO) and indium zinc oxide (IZO). Of these, ITO is preferable, considering that it is easy to obtain as a material for an anode of the organic EL element.

### <9. Sealing>

The preparation of the cathode may be followed by the provision of a protective layer for protecting the organic EL element. In order to stably use the organic EL element for a long period of time, the provision of the protective layer and/or a protective cover to externally protect the element is preferred. As the protective layer, suitable examples thereof are a high-molecular weight compound, a metal oxide, a metal fluoride, and a metal boride. As the protective cover, suitable examples thereof are a glass plate, a plastic plate with a surface having been subjected to treatment for lowering water permeability, and a metal. A preferable method is to laminate the cover onto the substrate of the element with a thermosetting resin or a photo-curing resin to seal the element. The use of a spacer to hold a space easily prevents the element from being damaged. Filling the space with an inert gas such as nitrogen or argon can prevent oxidation of the cathode, and furthermore, placing a desiccant such as barium oxide in the space easily prevents water adsorbed on the element during the production process from damaging the element. Employing one or more measures among these is preferred.

### <10. Substrate>

As the substrate of the organic EL element according to the present invention, a material which satisfies the mechanical strength required for an organic EL element is employed.

An organic EL element of bottom emission type employs a substrate transparent to visible light. Suitable examples thereof are, specifically, substrates made of glass, such as soda glass and no-alkali glass; a transparent plastic, such as an acrylic resin, a methacrylic resin, a polycarbonate resin, a polyester resin and a nylon resin; and silicon.

In addition to the substrates that may be used for the organic EL element of bottom emission type, an organic EL element of a top emission type can employ substrates made of a simple metal of copper, silver, gold, platinum, tungsten, titanium, tantalum or niobium, an alloy of these metals, or stainless steel.

The thickness of the substrate is preferably 0.1 to 10 mm, more preferably 0.25 to 2 mm, though depending upon the mechanical strength required.

### Applications

The organic EL element of the present invention is favorably used as a picture element of a matrix system or a segment system in an image display apparatus. Further, the organic EL element is favorably used also as a surface emission light source without forming a picture element.

Specifically, the organic EL element of the present invention is favorably used for a display apparatus in, e.g., computers, televisions, portable terminals, cellular phones, car navigations, markings, sign boards and view finders of video cameras, and for light irradiation apparatus in, e.g., back lighting, electrophotography, illumination, resist exposure, reading apparatus, interior illumination and optical communication systems.

### EXAMPLES

The present invention will next be described in more detail with reference to the following examples. However, the present invention should not be construed as being limited thereto.

### Example 1

Example 1 is described with reference to the following schemata.

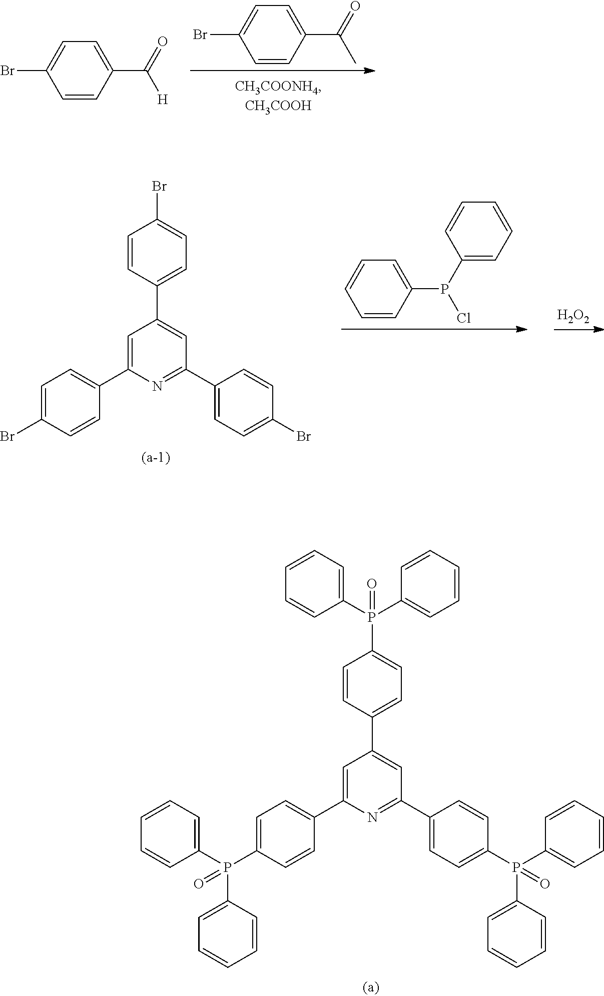

### (i) Synthesis of 2,4,6-tris(4-bromophenyl)pyridine (a-1)

To a round-bottom flask, 4.74 g (25.6 mmol) of 4-bromobenzaldehyde, 10.2 g (51.2 mmol) of 4-bromoacetophenone, 39.5 g (512 mmol) of ammonium acetate and 45 ml of acetic acid were introduced and stirred at 150° C. for 4 hours and then cooled to room temperature. Thereafter, 50 ml of water was added to the mixture and stirred for 1 hour. The mixture was filtered off and the resulting yellow solid was dissolved in chloroform. Then, the solvent was distilled off under reduced pressure to prepare an oily substance. To the oily substance, 40 ml of ethanol was added and stirred for 30 min while refluxing. The temperature of the mixture was returned to room temperature and the mixture was filtered off to prepare a white solid. This white solid was identified as 2,4,6-tris(4-bromophenyl)pyridine by ¹H-NMR and mass spectrometry. The amount (yield) was 5.36 g (39%).

### (ii) Synthesis of Phosphine Oxide Compound (a)

1.0 g (1.84 mmol) of 2,4,6-tris(4-bromophenyl)pyridine was dissolved in 15 ml of dehydrated THF and cooled to −78° C. Into the resulting solution, 3.5 ml (5.65 mmol) of a 1.6 M hexane solution of n-BuLi was dropped and stirred at the same temperature for 1 hour. Furthermore, 1.25 g (5.65 mmol) of chlorodiphenylphosphine was dropped into the solution and the temperature was gradually increased to room temperature and stirred overnight. After 6 ml of aqueous hydrogen peroxide (30%) was added, the mixture was stirred at room temperature for 1 hour.

To the mixture, a sodium sulfite aqueous solution was added and thereby hydrogen peroxide was reduced. Thereafter, an organic phase was extracted by adding chloroform/brine. The extract was dried over magnesium sulfate and the solvent was distilled off under reduced pressure to prepare a mixture of a yellow oily substance and a white solid. This mixture was purified by a silica gel column chromatography to thereby prepare a white solid. This white solid was identified as a phosphine oxide compound (a) represented by the above formula (a) by ¹H-NMR and mass spectrometry. The amount (yield) was 0.30 g (18%).

The identification data of the phosphine oxide compound (a) are as follows. ¹H-NMR (270 MHz, CDCl₃) ppm: 8.28-8.24 (m, 4H), 7.95 (s, 2H), 7.90-7.80 (m, 8H), 7.74-7.68 (m, 12H), 7.61-7.54 (m, 6H), 7.53-45 (m, 12H).

### Mass Spectrometry (FAB+); 908 [M+H]

The ¹H-NMR spectrum was determined by using a JNM EX270 (270 MHz) manufactured by JEOL and deuterated chloroform as a solvent. The mass spectrometry was carried out by using JMS-SX102A manufactured by JEOL and m-nitrobenzyl alcohol as a matrix.

### Example 2

Example 2 is described with reference to the following schemata.

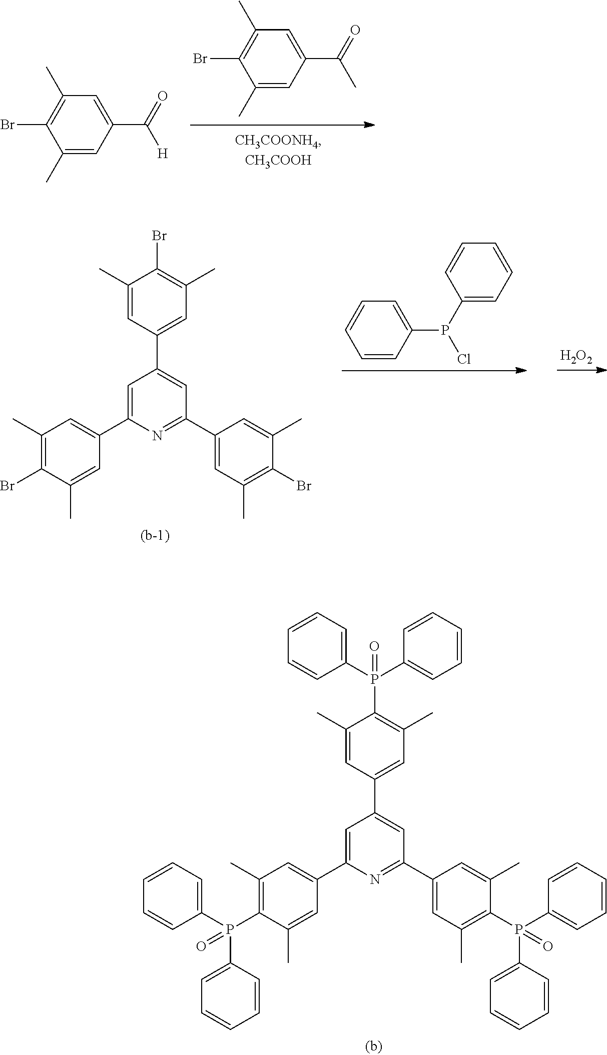

### (i) Synthesis of 2,4,6-tris(3,5-dimethyl-4-bromophenyl)pyridine (b-1)

To a round-bottom flask, 4.30 g (20.2 mmol) of 3,5-dimethyl-4-bromobenzaldehyde, 9.17 g (40.4 mmol) of 3,5-dimethyl-4-bromoacetophenone, 31.1 g (404 mmol) of ammonium acetate and 40 ml of acetic acid were introduced and stirred at 150° C. for 4 hours and then cooled to room temperature. Thereafter, 50 ml of water was added to the mixture and stirred for 1 hour. The mixture was filtered off and the resulting yellow solid was dissolved in chloroform. Then, the solvent was distilled off under reduced pressure to prepare an oily substance. To the oily substance, 40 ml of ethanol was added and stirred for 30 min while refluxing. The temperature of the mixture was returned to room temperature and the mixture was filtered off to prepare a white solid. This white solid was identified as 2,4,6-tris-(3,5-dimethyl-4-bromophenyl)pyridine by ¹H-NMR and mass spectrometry. The amount (yield) was 3.68 g (29%).

### (ii) Synthesis of Phosphine Oxide Compound (b)

1.0 g (1.59 mmol) of 2,4,6-tris-(3,5-dimethyl-4-bromophenyl)pyridine was dissolved in 15 ml of dehydrated THF and cooled to −78° C. Into the resulting solution, 3.1 ml (4.93 mmol) of a 1.6 M hexane solution of n-BuLi was dropped and stirred at the same temperature for 1 hour. Furthermore, 1.09 g (4.93 mmol) of chlorodiphenylphosphine was dropped and the temperature was gradually increased to room temperature and stirred overnight. After 6 ml of aqueous hydrogen peroxide (30%) was added, the mixture was stirred at room temperature for 1 hour.

To the mixture, a sodium sulfite aqueous solution was added and thereby hydrogen peroxide was reduced. Thereafter, an organic phase was extracted by adding chloroform/brine. The extract was dried over magnesium sulfate and the solvent was distilled off under reduced pressure to prepare a mixture of a yellow oily substance and a white solid. This mixture was purified by a silica gel column chromatography and thereby a white solid was prepared. This white solid was identified as a phosphine oxide compound (b) represented by the above formula (b) by ¹H-NMR and mass spectrometry. The amount (yield) was 0.19 g (12%).

The identification data of the phosphine oxide compound (b) are as follows. ¹H-NMR (270 MHz, CDCl₃) ppm: 8.39-8.34 (m, 4H), 7.92 (s, 2H), 7.90-7.78 (m, 8H), 7.74-7.67 (m, 12H), 7.62-7.54 (m, 6H), 7.53-7.40 (m, 12H), 2.58 (s, 12H), 2.42 (s, 6H).

### Mass Spectrometry (FAB+); 992 [M+H]

### Example 3

Example 3 is described with reference to the following schemata.

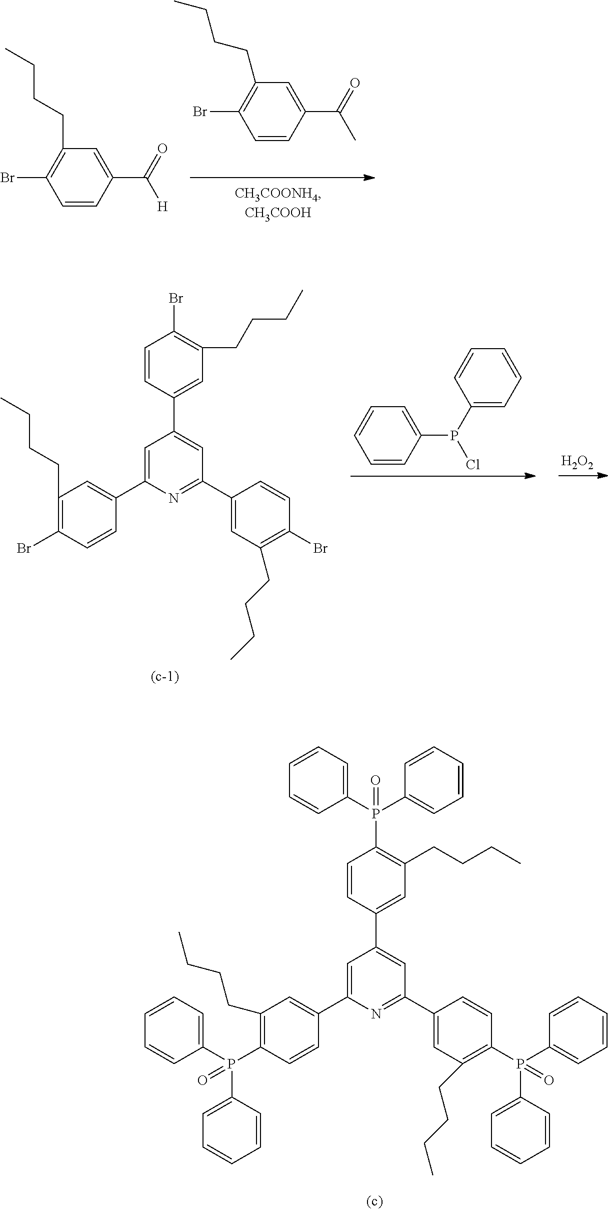

### (i) Synthesis of 2,4,6-tris(3-butyl-4-bromophenyl)pyridine (c-1)

To a round-bottom flask, 6.07 g (25.2 mmol) of 3-butyl-4-bromobenzaldehyde, 12.9 g (50.4 mmol) of 3-butyl-4-bromoacetophenone, 38.8 g (504 mmol) of ammonium acetate and 45 ml of acetic acid were introduced and stirred at 150° C. for 4 hours and then cooled to room temperature. Thereafter, 50 ml of water was added to the mixture and stirred for 1 hour. The mixture was filtered off and the resulting yellow solid was dissolved in chloroform. After the solvent was distilled off under reduced pressure, an oily substance was prepared. To the oily substance, 40 ml of ethanol was added and stirred for 30 min while refluxing. The temperature of the mixture was returned to room temperature and the mixture was filtered off to prepare a white solid. This white solid was identified as 2,4,6-tris-(3-butyl-4-bromophenyl)pyridine by ¹H-NMR and mass spectrometry. The amount (yield) was 4.31 g (24%).

### (ii) Synthesis of Phosphine Oxide Compound (c)

1.0 g (1.4 mmol) of 2,4,6-tris-(3-butyl-4-bromophenyl)pyridine was dissolved in 15 ml of dehydrated THF and cooled to −78° C. Into the resulting solution, 2.7 ml (4.34 mmol) of a 1.6 M hexane solution of n-BuLi was dropped and stirred at the same temperature for 1 hour. Furthermore, 0.96 g (4.34 mmol) of chlorodiphenylphosphine was dropped and the temperature was gradually increased to room temperature and the mixture was stirred overnight. After 6 ml of aqueous hydrogen peroxide (30%) was added, the mixture was stirred at room temperature for 1 hour.

To the mixture, a sodium sulfite aqueous solution was added and thereby hydrogen peroxide was reduced. Thereafter, an organic phase was extracted by adding chloroform/brine. The extract was dried over magnesium sulfate and the solvent was distilled off under reduced pressure to prepare a mixture of a yellow oily substance and a white solid. This mixture was purified by a silica gel column chromatography and thereby a white solid was prepared. This white solid was identified as a phosphine oxide compound (c) represented by the above formula (c) by ¹H-NMR and mass spectrometry. The amount (yield) was 0.24 g (16%).

The identification data of the phosphine oxide compound (c) are as follows. ¹H-NMR (270 MHz, CDCl₃) ppm: 8.30-8.20 (m, 4H), 7.90 (s, 2H), 7.92-7.82 (m, 5H), 7.74-7.67 (m, 12H), 7.62-7.54 (m, 6H), 7.53-7.40 (m, 12H), 2.50-2.40 (m, 6H), 1.40-1.20 (s, 12H), 0.85-0.76 (m, 9H).

### Mass Spectrometry (FAB+); 1076 [M+H]

### Example 4

Example 4 is described with reference to the following schemata.

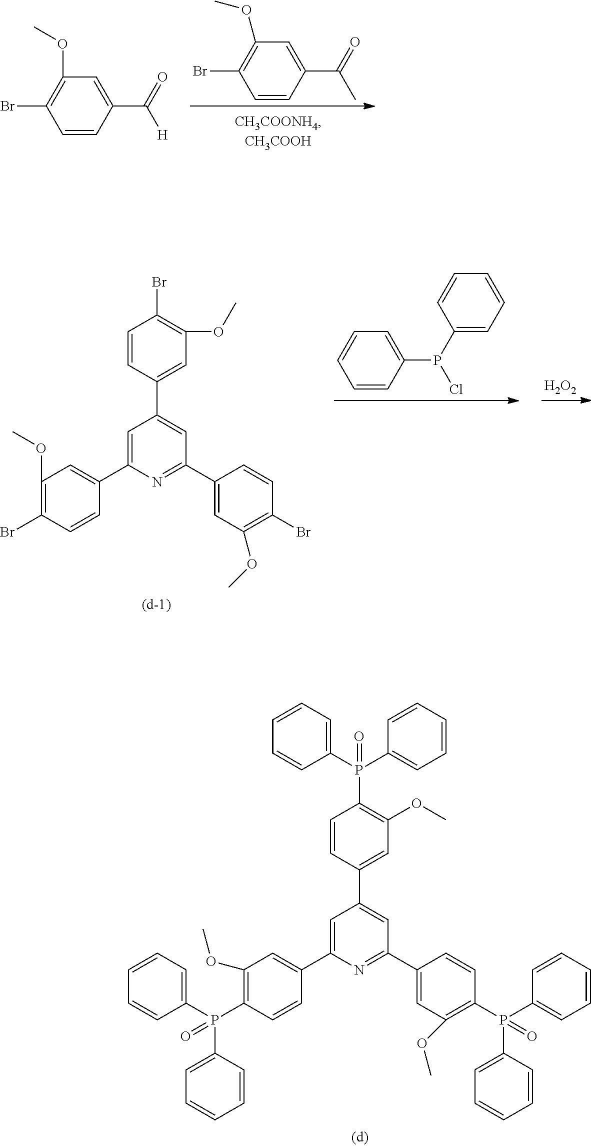

### (i) Synthesis of 2,4,6-tris(3-methoxy-4-bromophenyl)pyridine (d-1)

To a round-bottom flask, 4.37 g (20.3 mmol) of 3-methoxy-4-bromobenzaldehyde, 9.30 g (40.6 mmol) of 3-methoxy-4-bromoacetophenone, 30.9 g (406 mmol) of ammonium acetate and 40 ml of acetic acid were introduced and stirred at 150° C. for 4 hours and then cooled to room temperature. Thereafter, 50 ml of water was added to the mixture and stirred for 1 hour. The mixture was filtered off and the resulting yellow solid was dissolved in chloroform. After the solvent was distilled off under reduced pressure, an oily substance was prepared. To the oily substance, 40 ml of ethanol was added and stirred for 30 min while refluxing. The temperature of the mixture was returned to room temperature and the mixture was filtered off to prepare a white solid. This white solid was identified as 2,4,6-tris-(3-methoxy-4-bromophenyl)pyridine by ¹H-NMR and mass spectrometry. The amount (yield) was 3.65 g (18%).

### (ii) Synthesis of Phosphine Oxide Compound (d)

1.0 g (1.0 mmol) of 2,4,6-tris-(3-methoxy-4-bromophenyl)pyridine was dissolved in 15 ml of dehydrated THF and cooled to −78° C. Into the resulting solution, 1.94 ml (3.10 mmol) of a 1.6 M hexane solution of n-BuLi was dropped and stirred at the same temperature for 1 hour. Furthermore, 0.68 g (3.10 mmol) of chlorodiphenylphosphine was dropped and the temperature was gradually increased to room temperature and stirred overnight. After 6 ml of aqueous hydrogen peroxide (30%) was added, the mixture was stirred at room temperature for 1 hour.

To the mixture, a sodium sulfite aqueous solution was added and thereby hydrogen peroxide was reduced. Thereafter, an organic phase was extracted by adding chloroform/brine. The extract was dried over magnesium sulfate and the solvent was distilled off under reduced pressure to prepare a mixture of a yellow oily substance and a white solid. This mixture was purified by a silica gel column chromatography and thereby a white solid was prepared. This white solid was identified as a phosphine oxide compound (d) represented by the above formula (d) by ¹H-NMR and mass spectrometry. The amount (yield) was 0.10 g (10%).

The identification data of the phosphine oxide compound (d) are as follows. ¹H-NMR (270 MHz, CDCl₃) ppm: 8.35-8.25 (m, 4H), 7.95 (s, 2H), 7.89-7.78 (m, 5H), 7.74-7.68 (m, 12H), 7.61-7.53 (m, 6H), 7.53-7.43 (m, 12H), 2.89 (s, 3H), 2.75 (s, 6H).

### Mass Spectrometry (FAB+): 1076 [M+H]

### <Evaluation of Spectroscopic Characteristics>

The spectroscopic characteristics of the phosphine oxide compounds (a) to (d) were evaluated by measuring a chloroform solution of each of the phosphine oxide compounds (a) to (d) using a fluorospectrophotometer FP-6500 manufactured by JASCO. The evaluation results are shown in Table 1.

### Example 5

### Preparation of Deposition Film-Having Substrate

An ITO film-having glass substrate was cleaned by applying an ultrasonic wave thereto in an alkali detergent for 30 min. After the cleaning, a fluorocarbon film was formed as an anode buffer layer on the substrate by high-frequency plasma with CHF₃ gas using a reactive ion etching device (Samco RIE-2001P) to prepare an anode buffer layer-having substrate (1).

Next, a hole-transporting material represented by the following formula (15) having a weight average molecular weight, as determined by Gel permeation chromatography (GPC) relative to polystyrene, of 100,000 (hereinafter sometimes referred to “pEtCz”), an electron-transporting material represented by the following formula (8) (hereinafter sometimes referred to “Na222Tz”) and a blue phosphorescent compound represented by the following formula (10) (hereinafter sometimes referred to “BG19”) were dissolved in toluene so that the solid component concentration was 3.2% by mass, to prepare a luminescent layer-forming material (1). The mass ratio of pEtCz to Na222Tz was 2:1 and the proportion of the blue phosphorescent compound was 10% by mass based on all the solid components.

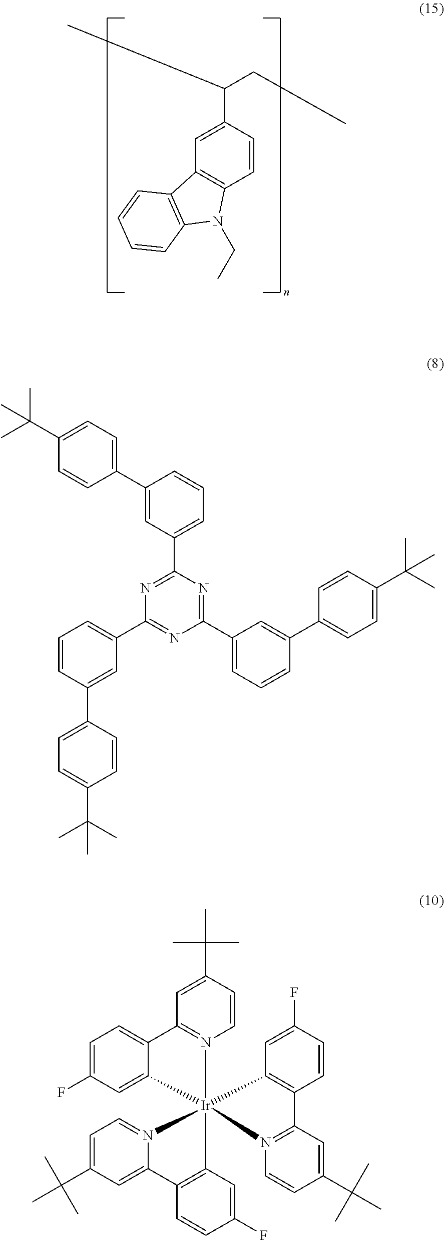

The luminescent layer-forming material (1) was applied on the anode buffer layer-having substrate (1) by a spin coating method in conditions such that the rotation number was 3,000 rpm and the coating time was 30 sec, and allowed to stand at 140° C. in a nitrogen atmosphere for 1 hour to form a luminescent layer. Thereby, the luminescent layer-having substrate (1) was prepared.

The luminescent layer-having substrate (1) was introduced into a vacuum deposition room and the compound (a) was deposited on the luminescent layer in the following conditions by a vacuum deposition device to prepare a deposition film-having substrate.

### Deposition Conditions:

Set Film thickness: 200 Å
Shape of deposition film: a rectangle of 3 mm×4 mm
Cell temperature: 380° C.
Heating of the substrate: no heating

### Pressure: 3.0×10⁻⁵ Pa

Deposition rate: 0.05 Å/sec, 0.1 Å/sec, 0.5 Å/sec, 2.0 Å/sec or 4.0 Å/sec

For each deposition rate, 10 deposition film (phosphine oxide deposition film)-having substrates were prepared. Using a stylus surface profiler (ULVAC Dektak 6), the film thickness and the film thickness difference of each deposition film were measured. The film thickness of the deposition film was taken as an average of the measurement values in measuring 15,000 positions present in a 2,000 μm straight line with almost the same distance in the center part. The resulting film thickness differences (namely, the difference between the maximum and the minimum of the thicknesses among the 10 substrates for each deposition rate) are shown in Table 2.

### Examples 6 to 8

In each example, deposition film-having substrates were prepared in the same manner as that of Example 5 except for changing the compound (a) into each of the compounds (b) to (d). The film thickness differences of the deposition films were measured. The results are shown in Table 2.

### Comparative Examples 1 to 5

In each example, deposition film-having substrates were prepared in the same manner as that of Example 5, except for changing the compound (a) into each of the compounds (e) to (i) represented by the following formulas (e) to (i), respectively. The film thickness differences of the deposition films were measured. The results are shown in Table 2.

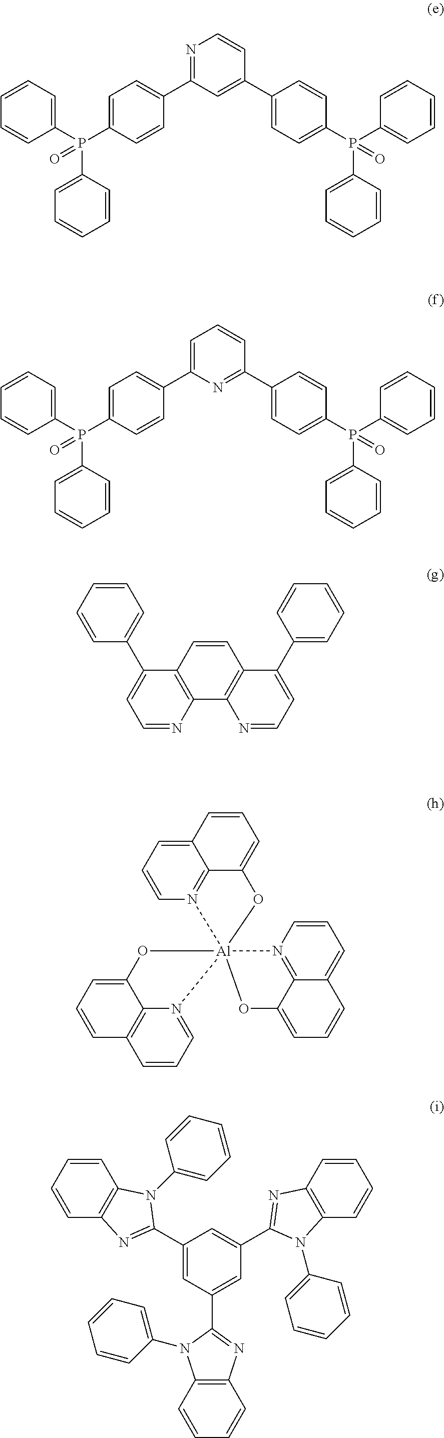

### Example 9

### Preparation of Organic El Element

The luminescent layer-having substrate (1) was introduced into a vacuum deposition room and the compound (a) was deposited on the luminescent layer by a vacuum deposition device under the following conditions to form a deposition film.

### Deposition Conditions:

Set Film thickness: 200 Å
Cell temperature: 380° C.
Heating of substrate: no heating

### Pressure: 3.0×10⁻⁵ Pa

Deposition rate: 0.1 Åsec

As a cathode buffer layer, a NaF layer having a thickness of 50 Å was formed on the deposition film and an Al layer having a thickness of 1,500 Å was formed as a cathode.

Finally, a glass protective cover (sealing material) was placed on the substrate so as to overspread each layer formed on the substrate and was adhered to the substrate by a UV curing epoxy resin, followed by irradiation with ultraviolet rays to complete sealing. Thus, an organic EL element 1 was fabricated.

### <Evaluation of Luminescence Characteristics>

The organic EL element 1 was energized stepwise with use of a constant-voltage source current meter (SM2400 manufactured by Keithley Instruments Inc.) and the luminescent intensity of the organic EL element 1 was measured by a luminance meter (BM-9 manufactured by Topcon Corporation). As a result, the luminescence starting voltage, the luminescence efficiency (ratio of luminescent intensity to current density at the time of lighting of 100 cd/m²) and the electric power efficiency (ratio of electric power to total luminous flux) were determined.

Furthermore, nine organic EL elements 1 were prepared using the same method and the luminescence characteristics were evaluated by the same method. The average of the measurement values of the ten organic EL elements 1 is shown in Table 3. The evaluation results were standardized based on the measurement value in Comparative Example 6 as described below. Examples 10 to 12 and Comparative Examples 6 to 11 were evaluated in the same manner

### Examples 10 to 12

The organic EL elements 2 to 4 were prepared respective ten ones in the same manner as that of Example 9, except for changing the compound (a) to each of the compounds (b) to (d). The luminescence characteristics of each of the organic EL elements 2 to 4 were evaluated in the same manner as that of the organic EL element 1. The results are shown in Table 3.

### Comparative Example 6

Ten elements (organic EL element 5) were prepared by the same method as that of Example 9, except for no deposition of the compound (a). The luminescence characteristics of the organic EL element 5 were evaluated in the same manner as that of the organic EL element 1. The results are shown in Table 3.

### Comparative Examples 7 to 11

Ten each of the organic EL elements 6 to 10 were prepared, respectively, in the same manner as that of Example 9, except for changing the compound (a) to each of the compounds (e) to (f). The luminescence characteristics of each of the organic EL elements 6 to 10 were evaluated in the same manner as that of the organic EL element 1. The results are shown in Table 3.

### Example 13

According to the method described in JP-A-2005-200638 laid-open on Jul. 28, 2005 (at paragraph [0112]) and US 2007/167588 Al laid-open on Jul. 19, 2007 (at paragraphs [0151] to [0158]), incorporated herein by reference, the compound represented by the following formula (hereinafter referred to “viHMTPD”) was synthesized and polymerized to prepare a charge-transporting polymer having a weight average molecular weight, as determined by GPC relative to polystyrene, of 70,000 (hereinafter referred to “pHMTPD”).

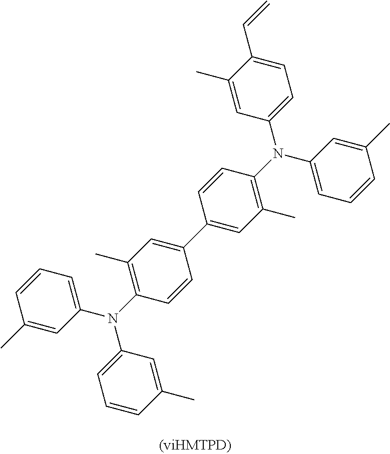

To 100% by mass of pHMTPD, 5% by mass of F4TCNQ, which is an electron-receiving compound and can form a charge transfer complex, was added and they were dissolved in toluene so that the solid concentration was 0.8% by mass. Thus, an anode buffer layer forming material was prepared.

An ITO film-having glass substrate was cleaned in an alkali detergent by applying an ultrasonic wave thereto for 30 min. Thereafter, the anode buffer layer forming material was applied on the substrate at a rotation number of 3,000 rpm for a coating time of 30 sec by a spin coating method and allowed to stand in a nitrogen atmosphere at 210° C. for 1 hour to form an anode buffer layer. Thus, an anode buffer layer-having substrate (2) was prepared.

Ten organic EL elements 11 were prepared in the same procedure as that of Example 9, except for using the anode buffer layer-having substrate (2) in place of the anode buffer layer-having substrate (1). The organic EL elements 11 were evaluated in the same manner as that of the organic EL element 1. The average of the measurement values of the ten organic EL elements 11 is shown in Table 4. The evaluation results were standardized based on the measurement value of Comparative Example 12 as described later. Examples 14 to 16 and Comparative Examples 12 to 17 were evaluated in the same manner

### Examples 14 to 16

Organic EL elements 12 to 14 were prepared respective ten ones in the same manner as that of Example 13, except for changing the compound (a) to each of the compounds (b) to (d) respectively. The luminescence characteristics of each of the organic EL elements 12 to 14 were evaluated in the same manner as that of the organic EL element 1. The evaluation results are shown in Table 4.

### Comparative Example 12

Ten organic EL elements 15 were prepared in the same procedure as that of Example 13, except for no deposition of the compound (a) on the luminescent layer. The luminescence characteristics of the organic EL element 15 were evaluated in the same manner as that of the organic EL element 1. The evaluation results are shown in Table 4.

### Comparative Examples 13 to 17

Organic EL elements 16 to 20 were prepared respective ten ones in the same manner as that of Example 13, except for changing the compound (a) to each of the compounds (e) to (i) respectively. The luminescence characteristics of each of the organic EL elements 16 to 20 were evaluated in the same manner as that of the organic EL element 1. The evaluation results are shown in Table 4.

### Example 17

Ten organic EL elements 21 were prepared in the same procedure as that of Example 13, except for changing the deposition rate of the compound (a) to 4.0 Å/sec. The film thickness of the deposition film was measured by the same method as that of Example 5. The luminescence characteristics of the organic EL element 21 were evaluated in the same manner as that of the organic EL element 1. The evaluation results on element (21-α) having the maximum in thickness and element (21-β) having the minimum in thickness are shown in Table 5.

### Comparative Examples 18 to 20

Ten each of organic EL elements 22 to 24 were prepared, respectively, in the same manner as that of Example 17 except for changing the compound (a) to each of the compounds (b) to (d). The film thickness of each deposition film was measured by the same method as that of Example 5. The luminescence characteristics of each of the organic EL elements 22 to 24 were evaluated in the same manner as that of the organic EL element 1. The evaluation results of elements (22-α, 23-α, 24-α) each having the maximum in thickness and elements (21-β, 23-β, 24-β) each having the minimum in thickness are shown in Table 5.

### Comparative Examples 18 to 22

Ten each of organic EL elements 25 to 29 were prepared, respectively, in the same manner of that of Example 17, except for changing the compound (a) to each of the compounds (e) to (i). The film thickness of each deposition film was measured by the same method as that of Example 5. The luminescence characteristics of each of the organic EL elements 25 to 29 were evaluated in the same manner as that of the organic EL element 1. The evaluation results of the elements having the maximum in thickness (25-α, 26-α, 27-α, 28-α, 29-α) and the elements having the minimum in thickness (25-β, 26-β, 27-β, 28-β, 29-β) are shown in Table 5.

TABLE 1

| Compound | Energy gap (eV) | T1 level (eV) |
|---|---|---|
| a | 3.55 | 2.72 |
| b | 3.50 | 2.71 |
| c | 3.56 | 2.72 |
| d | 3.48 | 2.70 |
| e | 3.80 | 2.80 |
| f | 3.70 | 2.70 |
| g | 3.66 | 2.61 |
| h | 3.50 | 2.68 |
| i | 3.14 | 2.00 |

TABLE 2

| | | Film | Film | Film | Film | Film |
|---|---|---|---|---|---|---|
| | | thickness | thickness | thickness | thickness | thickness |
| | | Difference | Difference | Difference | Difference | Difference |
| | | (Å) at a | (Å) at a | (Å) at a | (Å) at a | (Å) at a |
| | | deposition | deposition | deposition | deposition | deposition |
| | | rate of | rate of | rate of | rate of | rate of |
| | Compound | 0.05 Å/sec | 0.1 Å/sec | 0.5 Å/sec | 2.0 Å/sec | 4.0 Å/sec |
| Ex. 5 | a | 5.2 | 5.4 | 5.2 | 5.6 | 6.2 |
| Ex. 6 | b | 6.0 | 6.2 | 6.2 | 6.5 | 6.6 |
| Ex. 7 | c | 5.6 | 5.6 | 5.8 | 5.9 | 6.5 |
| Ex. 8 | d | 7.2 | 8.9 | 9.9 | 10.2 | 15.6 |
| Com. Ex. 1 | e | 8.8 | 17.2 | 29.2 | 38.8 | 44.4 |
| Com. Ex. 2 | f | 10.2 | 23.2 | 31.6 | 40.0 | 45.2 |
| Com. Ex. 3 | g | 13.6 | 20.4 | 42.0 | 57.6 | 64.4 |
| Com. Ex. 4 | h | 12.0 | 18.4 | 33.2 | 38.4 | 42.0 |
| Com. Ex. 5 | i | 10.8 | 16.4 | 40.4 | 46.4 | 52.4 |

As is clear from Table 2, the deposition films of Examples 5 to 8 (compounds a to d) have a smaller film thickness difference as compared with the deposition films of Comparative Examples 1 to 5 regardless of the deposition rate, and can be formed stably even if the deposition rate is increased.

TABLE 3

| | | Anode buffer | | | Relative | |
|---|---|---|---|---|---|---|
| | | layer having | Deposition | Relative | luminescence | Relative electric |
| | Element | substrate | film | voltage | efficiency | power efficiency |
| Ex. 9 | 1 | 1 | a | 0.92 | 1.07 | 1.17 |
| Ex. 10 | 2 | 1 | b | 0.93 | 1.07 | 1.15 |
| Ex. 11 | 3 | 1 | c | 0.94 | 1.08 | 1.15 |
| Ex. 12 | 4 | 1 | d | 0.94 | 1.05 | 1.12 |
| Com. Ex. 6 | 5 | 1 | None | 1 | 1 | 1 |
| Com. Ex. 7 | 6 | 1 | e | 0.96 | 1.01 | 1.05 |
| Com. Ex. 8 | 7 | 1 | f | 0.97 | 1.02 | 1.06 |
| Com. Ex. 9 | 8 | 1 | g | 1.05 | 0.95 | 0.90 |
| Com. Ex. | 9 | 1 | h | 1.01 | 0.97 | 0.96 |
| 10 | | | | | | |
| Com. Ex. | 10 | 1 | i | 1.01 | 0.92 | 0.92 |
| 11 | | | | | | |

In each of Examples 9 to 12, the voltage is lowered, the luminescence efficiency is increased and the electric power efficiency is increased as compared with Comparative Example 6 in which the deposition film of the phosphine oxide compound was not formed. In Examples 9 to 12, these properties are greatly improved as compared with Comparative Examples 7 and 8.

TABLE 4

| | | Anode buffer | | | Relative | |
|---|---|---|---|---|---|---|
| | | layer having | Deposition | Relative | luminescence | Relative electric |
| | Element | substrate | film | voltage | efficiency | power efficiency |
| Ex. 13 | 11 | 2 | a | 0.87 | 1.07 | 1.24 |
| Ex. 14 | 12 | 2 | b | 0.88 | 1.08 | 1.23 |
| Ex. 15 | 13 | 2 | c | 0.90 | 1.06 | 1.18 |
| Ex. 16 | 14 | 2 | d | 0.91 | 1.06 | 1.16 |
| Com. Ex. | 15 | 2 | None | 1 | 1 | 1 |
| 12 | | | | | | |
| Com. Ex. | 16 | 2 | e | 0.95 | 1.04 | 1.09 |
| 13 | | | | | | |
| Com. Ex. | 17 | 2 | f | 0.94 | 1.03 | 1.09 |
| 14 | | | | | | |
| Com. Ex. | 18 | 2 | g | 1.02 | 0.96 | 0.94 |
| 15 | | | | | | |
| Com. Ex. | 19 | 2 | h | 1.00 | 0.95 | 0.97 |
| 16 | | | | | | |
| Com. Ex. | 20 | 2 | i | 1.02 | 1.01 | 1.00 |
| 17 | | | | | | |

In each of Examples 13 to 16, the voltage is lowered, the luminescence efficiency is increased and the electric power efficiency is increased as compared with Comparative Example 12 in which the deposition film of the phosphine oxide compound was not formed. In Examples 13 to 16, these properties are greatly improved as compared with Comparative Examples 13 to 14.

TABLE 5

| | | | Thickness of | | Relative | |
|---|---|---|---|---|---|---|
| | | Deposition | Deposition film | Relative | luminescence | Relative electric |
| | Element | film | (Å) | voltage | efficiency | power efficiency |
| Ex. 17 | 21-α | a | 204 | 0.87 | 1.07 | 1.24 |
| | 21-β | a | 198 | 0.88 | 1.07 | 1.22 |
| Ex. 18 | 22-α | b | 205 | 0.88 | 1.06 | 1.20 |
| | 22-β | b | 198 | 0.87 | 1.07 | 1.23 |
| Ex. 19 | 23-α | c | 204 | 0.90 | 1.06 | 1.18 |
| | 23-β | c | 198 | 0.90 | 1.07 | 1.19 |
| Ex. 20 | 24-α | d | 208 | 0.92 | 1.06 | 1.15 |
| | 24-β | d | 198 | 0.91 | 1.06 | 1.16 |
| Com. Ex. | 25-α | e | 230 | 0.97 | 1.03 | 1.06 |
| 18 | 25-β | e | 191 | 0.90 | 1.05 | 1.17 |
| Com. Ex. | 26-α | f | 233 | 0.97 | 1.04 | 1.07 |
| 19 | 26-β | f | 197 | 0.91 | 1.04 | 1.14 |
| Com. Ex. | 27-α | g | 254 | 1.06 | 0.96 | 0.91 |
| 20 | 27-β | g | 190 | 1.00 | 1.01 | 1.01 |
| Com. Ex. | 28-α | h | 233 | 1.03 | 0.99 | 0.99 |
| 21 | 28-β | h | 191 | 0.99 | 0.94 | 0.95 |
| Com. Ex. | 29-α | i | 238 | 1.04 | 1.00 | 0.96 |
| 22 | 29-β | i | 186 | 1.01 | 0.98 | 0.97 |

Each of the organic EL elements of Examples 17 to 20 in which the phosphine oxide compound of the present invention is used has a smaller film thickness difference (film thickness difference between element α and element β) and higher performance, and is more stable as compared with the elements in Comparative Examples 18 to 22.

The invention has been described in detail with reference to the above embodiments. However, the invention should not be construed as being limited thereto. It should further be apparent to those skilled in the art that various changes in form and detail of the invention as shown and described above may be made. It is intended that such changes be included within the spirit and scope of the claims appended hereto.

This application is based on Japanese Patent Application No. 2011-086565 filed Apr. 8, 2011, incorporated herein by reference in its entirety.

What is claimed is:

1. A compound represented by the following formula (1): 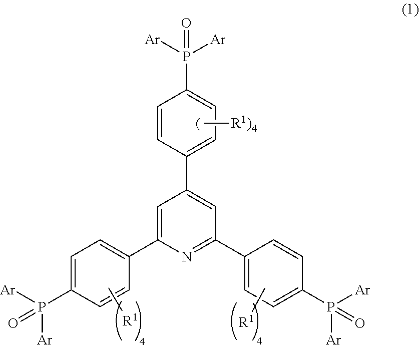
wherein in the formula (1), plural R¹ are each an alkyl group having 1 to 10 carbon atoms, an alkoxy group having 1 to 10 carbon atoms, a halogen atom, or a hydrogen atom, and may be the same as or different from one another; and plural Ar are each a monovalent substituted or unsubstituted aromatic group optionally containing a hetero atom, and may be the same as or different from one another.

2. The compound as claimed in claim 1, wherein all of the Ar groups are phenyl groups.

3. The compound as claimed in claim 1, wherein all of R¹ are each hydrogen atoms.

4. An organic electroluminescence element, comprising an anode, a luminescent layer, a phosphine oxide-containing layer and a cathode laminated in this order, the phosphine oxide-containing layer comprising a compound represented by the following formula (1): 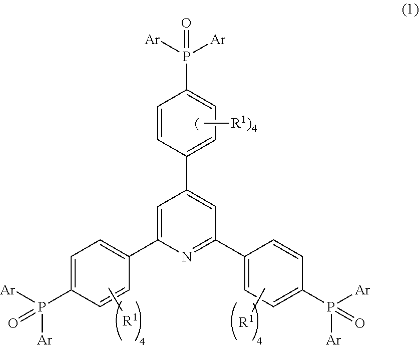
wherein in the formula (1), plural R¹ are each an alkyl group having 1 to 10 carbon atoms, an alkoxy group having 1 to 10 carbon atoms, a halogen atom, or a hydrogen atom, and may be the same as or different from one another; and plural Ar are each a monovalent substituted or unsubstituted aromatic group optionally containing a hetero atom, and may be the same as or different from one another.

5. The organic electroluminescence element as claimed in claim 4, further comprising an anode buffer layer adjacent to the anode between the anode and the luminescent layer.

6. A method for producing an organic electroluminescence element, comprising the steps of:
forming a phosphine oxide-containing layer by depositing a compound represented by the following formula (1) on a luminescent layer formed on an anode, and
forming a cathode on the phosphine oxide-containing layer; 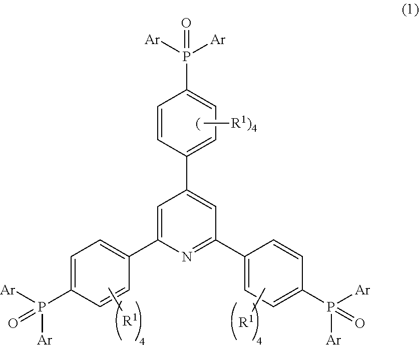
wherein in the formula (1), plural R¹ are each an alkyl group having 1 to 10 carbon atoms, an alkoxy group having 1 to 10 carbon atoms, a halogen atom, or a hydrogen atom, and may be the same as or different from one another; and plural Ar are each a monovalent substituted or unsubstituted aromatic group optionally containing a hetero atom, and may be the same as or different from one another.

7. A display apparatus comprising the organic electroluminescence element as claimed in claim 4.

8. A light irradiation apparatus comprising the organic electroluminescence element as claimed in claim 4.
